(19) United States
(12) Patent Application Publication
(10) Pub. No.: US 2001/0017772 A1
(43) Pub. Date: Aug. 30, 2001

(54) Emitters specifically for sub-sea applications

(75) Inventor: Anthony D. Marshall, Boverley (GB)

Correspondence Address: FISH & NEAVE, 1251 AVENUE OF THE AMERICAS, 50TH FLOOR, NEW YORK, NY, 10020-1105, US

(73) Assignee: Sea Marshall Rescue Systems, Ltd. (USA)

(21) Appl. No.: 09/792,373

(22) Filed: Feb. 23, 2001

(30) Foreign Application Priority Data
Feb. 25, 2000 (GB) 0004369.5

(51) Int. Cl. H05K 5/06; F21L 14/02

(52) U.S. Cl. 361/814; 362/157; 348/81

(57) ABSTRACT

The present invention provides apparatuses and methods for alleviating impact of underwater pressure upon submersible devices and emitters. An interior space of the casing of a submersible device may be filled up with fluid to reduce the impact of underwater pressure. The submersible device may further comprise a pressure adjusting bladder attached to the casing through a structure that permits flow of fluid from the casing into the bladder. The bladder may enable the device to cope with varying degrees of fluid expansion due to changes in surrounding pressure or temperature. The submersible device may also comprise a special type of fluid and specially designed internal components so that the presence and flow of the fluid within the device do not affect the performance of the components.

### BACKGROUND OF THE INVENTION

The present invention relates to improvements in and relating to submersible devices, particularly, but not exclusively, to emitters for indicating position to search craft during sea rescue operations.

In deep water, submersible devices may be exposed to considerable underwater pressure. Without outer reinforced supports, the casings of the devices may distort, be damaged, or crushed when exposed to the underwater pressure. Unfortunately, outer reinforced supports typically increase the weight and size of the casings significantly and interfere with the need to maintain small, lightweight, and portable casings.

In view of the foregoing, it would be desirable to provide apparatuses and methods for alleviating impact of underwater pressure upon submersible devices and emitters.

### SUMMARY OF THE INVENTION

It is therefore an object of the present invention to provide apparatuses and methods for alleviating impact of underwater pressure upon submersible devices.

In accordance with this and other objects of the invention, there are provided apparatuses and methods for alleviating impact of underwater pressure upon submersible devices and emitters for underwater applications. A casing of a submersible device may be filled up with fluid to reduce the impact of underwater pressure. Replacing the air inside the device with fluid may minimize the impact of underwater pressure on the structure. However, a sealed structure containing fluid such as oil may pose a potential storage problem. For example, at high enough temperature, the filling oil could expand and breach the seals. To compensate for this, the submersible device may further comprise a pressure adjusting bladder attached to the casing through a structure that permits a flow of fluid between the casing and the bladder. The pressure adjusting bladder may enable the device to cope with varying degrees of fluid expansion due to changes in surrounding pressure or temperature.

A submersible device may contain various internal components within its casing. For example, the submersible device may be an emitter device comprising control circuitry within its casing. As another example, the submersible device may be an underwater camera, such as a digital camera. If implemented with fluid within the casing, however, the fluid may damage or corrode the circuitry. Furthermore, the presence of fluid such as oil may cause temporal and/or spatial variation in the dielectric properties surrounding the circuitry, adversely affecting its performance. Accordingly, the submersible device may comprise a special type of fluid and specially designed internal components so that the presence and the flow of the fluid in the device do not affect performance of the internal components. The pressure adjusting bladder may further comprise a pressure gauge that controls the flow of the fluid between the casing and the bladder.

### BRIEF DESCRIPTION OF THE DRAWINGS

The above and other objects and advantages of the present invention will be apparent upon consideration of the following detailed description, taken in conjunction with the accompanying drawings, in which like reference characters refer to like parts throughout, and in which:

FIG. 1 is a perspective view of a first embodiment of the invention in a position indicating emitter comprising a casing and a pressure adjusting bladder loosely shrouding an antenna that are filled with fluid;

FIG. 2 is a cross-sectional view of the device of FIG. 1;

FIG. 3 is a close-up sectional view of the pressure adjusting bladder comprising a flexible waterproof shroud loosely enclosing the antenna and an open space between the shroud and the antenna that is filled with fluid from the emitter casing; and

FIG. 4 is a perspective view of an alternative embodiment of the present invention incorporating a pressure adjusting bladder made of a flexible waterproof material.

### DETAILED DESCRIPTION OF THE INVENTION

One aspect of the present invention provides a method of enabling a submersible device to withstand water pressure at depths by replacing the air inside the casing of the submersible device with fluid. The presence of a fluid within a casing may provide resistence against the impact of underwater pressure upon the device.

Preferably, the casing is completely sealed and waterproof. The casing may be buoyant. The casing may contain an aperture to allow access to the fluid. The aperture may also serve as a topping-up facility. The aperture may be sealed by a sealing screw with an “O” ring. However, the submersible device may be filled up with the fluid in any suitable manner.

Preferably, the fluid does not damage or corrode the device casing or any internal components of the submersible device. Furthermore, the fluid may have a suitable fluidity when the device is in use. The fluid may be non-corrosive oil with low temperature fluidity. However, any suitable fluid may be used, and the fluid may go through various states—gas or solid phases—at different stages of its use.

Another aspect of the present invention calls for a pressure adjusting bladder to be attached to the casing. An open end of the bladder may be attached to the casing through a structure that permits a flow of fluid between the casing and the bladder. By allowing a flow of fluid from the casing into the bladder, the present invention may enable the device to cope with varying degrees of fluid expansion due to changes in surrounding pressure or temperature or any other cause.

The pressure adjusting bladder may be made of flexible and waterproof material. The pressure adjusting bladder may further be made of thin and lightweight material. However, the pressure adjusting bladder may be made of any suitable material and may be constructed in any suitable structure, as long as it is capable of accommodating fluid expansion.

In an alternative embodiment of the present invention, the submersible device may further comprise a pressure gauge and a valve-like device connecting the casing and the pressure adjusting bladder. The valve-like device may control the flow level of fluid between the casing and the bladder based on the level of underwater pressure measured by the pressure gauge. For example, free flow of the fluid between the casing and the bladder may be allowed only after the reading of the pressure gauge exceeds a certain pre-set value. In another example, the flow level of the fluid between the casing and the bladder may be linearly related to the reading of the pressure gauge. However, any valve-like device may control the flow of fluid between the casing and the bladder in any suitable manner.

Another alternative embodiment of the present invention may comprise more than one pressure adjusting bladder.

In another alternative embodiment of the present invention, the submersible device may be an emitter comprising a power source and one or more radiation emitter and/or radiation receiver. The power source may be provided in the casing of the emitter. A control circuit may be provided in the casing. User operable controls for the control circuit may be provided on the casing. The air in the interior space of the casing may be replaced with the fluid before the intended use of the emitter.

The emitter may be a position indicating emitter, comprising one or more of a radiowave radiation emitter, a radiowave radiation receiver, and a light radiation emitter. However, the position indicating emitter may comprise any suitable components necessary for its intended function.

The radiowave radiation emitters and/or receivers may be mounted within the casing. Radiowave radiation emitters and receivers may include one or more antennas. The antenna may be mounted on the casing. One or more light radiation emitters may be mounted on the casing. The light radiation emitters may be incorporated into or mounted on the antenna. The position indicating emitter may additionally or alternatively have any other suitable structure to achieve its intended function.

In another alternative embodiment of the present invention, the pressure adjusting bladder in the position indicating emitter may be in form of a shroud enclosing an antenna mounted on the casing. The shroud may be flexible and waterproof. Preferably, there is a sufficient space between the shroud and the antenna to allow fluid from the casing to fill the bladder. By allowing the fluid from the casing to fill the bladder, the present invention may provide an automatic pressure adjusting bladder effect. It may thereby enable the position indicating emitter to cope with varying degrees of fluid expansion due to changes in surrounding pressure or temperature or any other cause.

Another aspect of the present invention calls for a special type of the fluid for the position indicating emitter. The fluid may be oil. Preferably, the fluid is non-corrosive and possesses a suitable fluidity when the position indicating emitter is in use. For example, the fluid may possess low temperature fluidity to be suitable for use during a sea rescue operation. In addition, the fluid may possess adequate dielectric properties and thermal and oxidation stability to be suitable to act as an insulating medium around radio frequency (RF) circuits. The fluid may be dried and degassed. The fluid may be transparent or translucent to help the visibility of a light radiation emitter, especially if the light radiation emitter is incorporated into or mounted on the antenna. However, any suitable fluid may be used, and the fluid may go through various states—gas or solid phases—at different stages of its use.

Yet another aspect of the present invention may include a special design of control circuitry for the position indicating emitter. The control circuitry may be so designed to dispense with variable tuned circuits or any other types of circuits that would be affected by the variation of dielectric properties due to the presence and flow of the fluid around the circuitry. However, the position indicating emitter of the present invention may comprise any suitably designed control circuitry.

The depth rating may be from surface waterproof standard to 300 meters in depth. However, the present invention may be applied to operation at any depth. The depth protected emitter may have a variety of applications for sport divers, commercial divers, and submarine escape apparatus for surface location in an emergency. Some embodiments of the present invention may be used for any applications other than emitters.

This application incorporates by reference the full details of Great Britain Patent Application No. 0004369.5, filed Feb. 25, 2000, entitled “IMPROVEMENTS IN AND RELATING TO EMITTERS SPECIFICALLY FOR SUB-SEA APPLICATIONS.” This application also incorporates by reference the full details of United patent application Ser. No. 09/225,987, filed Jan. 5, 1999, entitled “RADIO BEACON THAT USES A LIGHT EMITTER AS AN ANTENNA,” now U.S. Pat. No. 6,183,328, issued Feb. 6, 2001, and U.S. patent application Ser. No. 09/231,070, filed Jan. 14, 1999, entitled “IMPROVEMENTS IN AND RELATING TO EMITTERS.”

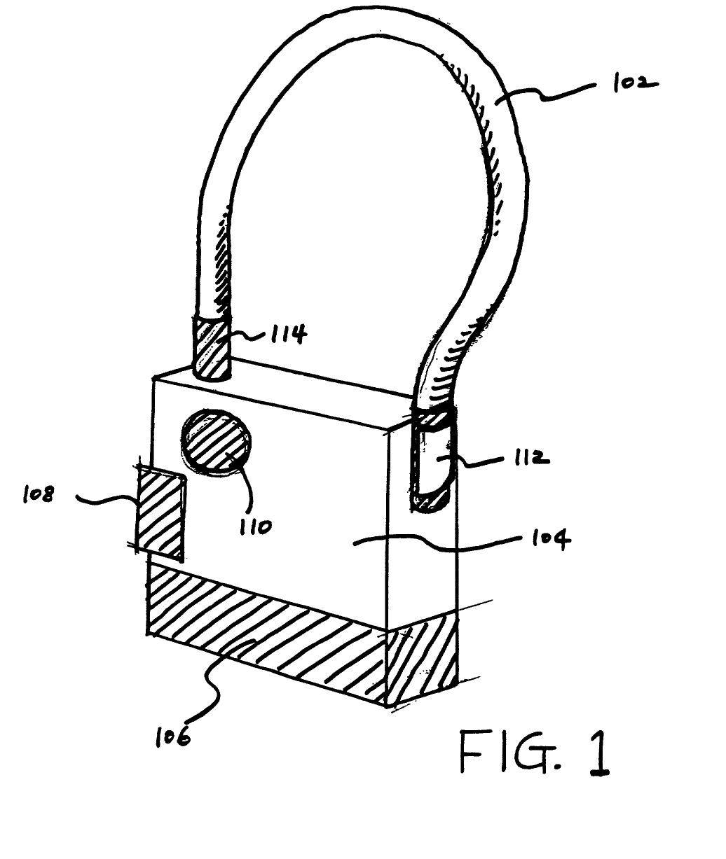

One embodiment of the present invention is illustrated in FIG. 1. As shown, emitter casing 104 may be provided with a pressure adjusting bladder 102. The pressure adjusting bladder may be attached to the casing through a structure 114 that permits a flow of fluid from and to the interior space of the emitter casing. The pressure adjusting bladder may be further provided with an arming switch 108, a control switch 110 (which may be omitted if desired), and an inner access cover 106.

The pressure adjusting bladder may be made of flexible waterproof material, and may loosely enclose an antenna of the emitter. The closed end of the pressure adjusting bladder extending away from structure 114 may be held in a grip-like device 112 in order to attach the closed end near to the casing and to make a loop so that a user may wear the bladder around his or her neck.

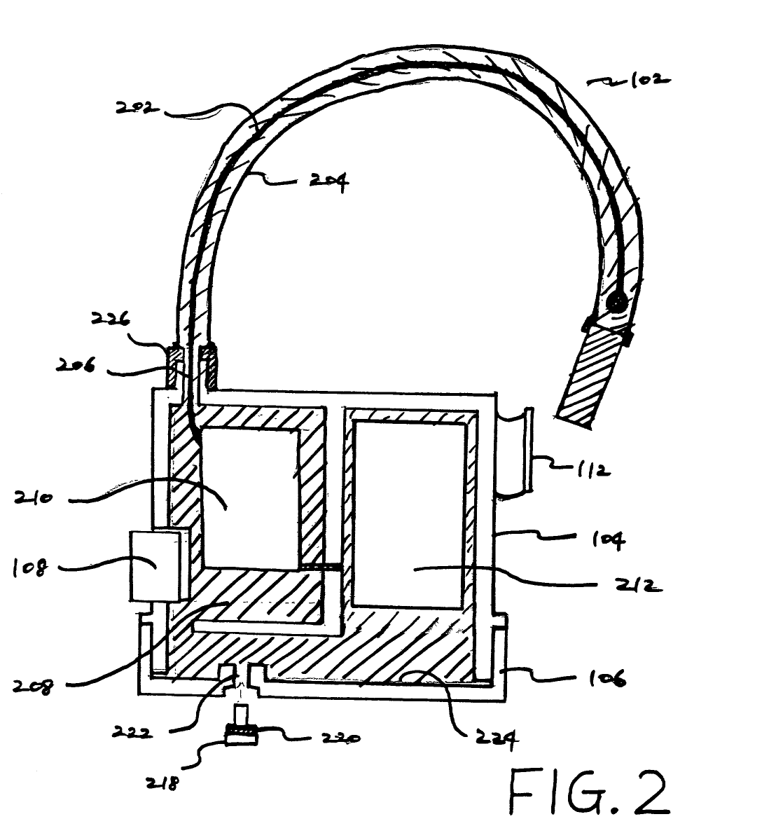

A cross-sectional view of this embodiment of the invention is illustrated in FIG. 2. As shown, the casing may house a power source 212 and control circuitry 210 for the emitter. The interior space of the casing not occupied by the above and other internal components of the emitter may be occupied by fluid 208.

The pressure adjusting bladder may be attached to the emitter casing through a structure 226 which may have an opening 206 to allow the flow of the fluid from the emitter casing. Opening 206 may include a valve or regulator.

The bottom of the emitter casing may be securely covered by an inner access cover 106. The inner access cover may provide access to power source 212, control circuitry 210, and/or other internal components of the emitter. The inner access cover may contain an aperture 222 that allows fluid to flow into and out of the interior space of the emitter casing. The aperture may be sealed by a sealing screw 218 with an “O” ring 220. The aperture may provide a topping-up facility for the fluid.

The casing and the bladder are preferably completely filled with the fluid.

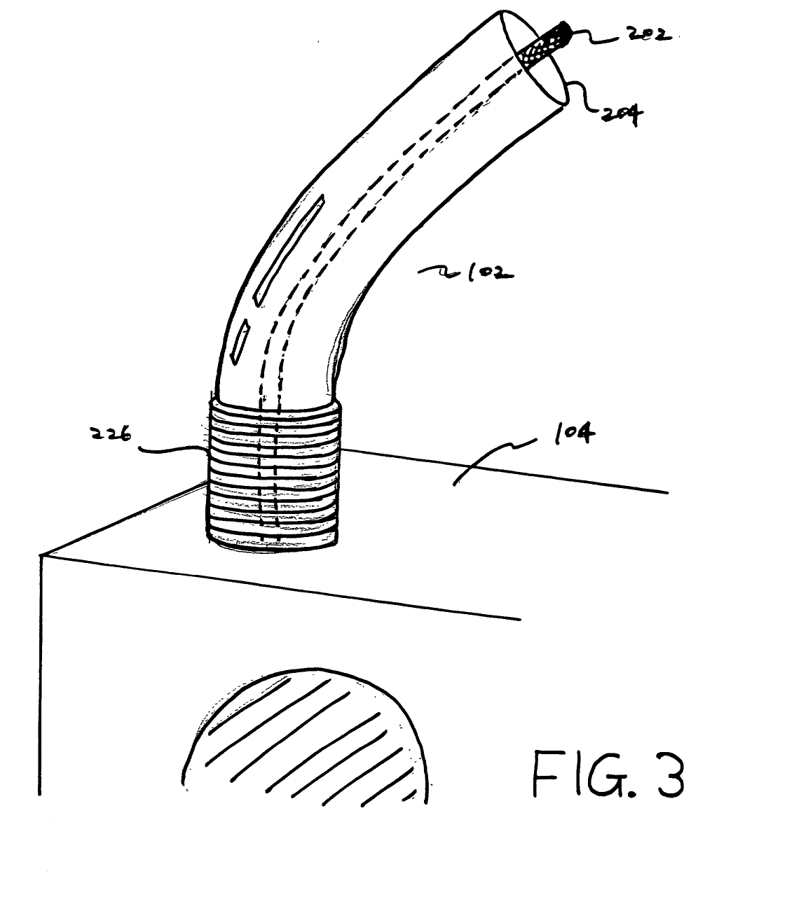

FIG. 3 illustrates a close-up sectional view of a pressure adjusting bladder 102 that may be used in an emitter device. Preferably, pressure adjusting bladder 102 may comprise a flexible waterproof shroud 204. The shroud may loosely enclose an antenna 202 of the emitter. Preferably, there is a sufficient space within the enclosure to allow the flow of fluid from the emitter casing through a structure 226 during fluid expansion. The antenna may comprise an electroluminescent light emitter, such as that described in the U.S. patent application No. 09/225,987, filed Jan. 5, 1999, now U.S. Pat. No. 6,183,328. In such case, the bladder shroud may be transparent or translucent to assist the effective performance of the light emitter incorporated into or mounted on the antenna.

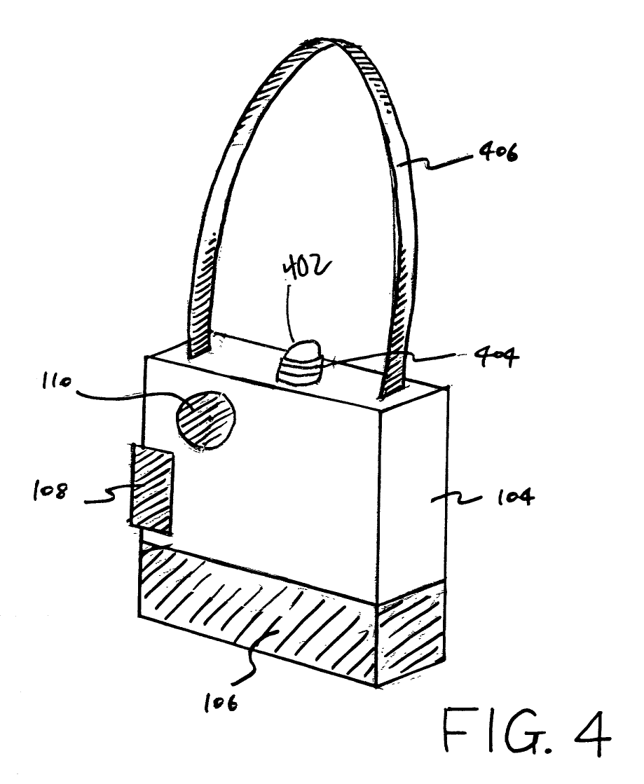

An alternative embodiment of the present invention is illustrated in FIG. 4. In this embodiment, a pressure bladder 402 may be completely separated from an antenna 406. The pressure bladder may be made of flexible, waterproof material and may be securely attached to a casing 104 through a structure 404 that permits flow of the fluid between the bladder and the interior space of the casing. The antenna in this embodiment is not necessarily shrouded by any pressure adjusting bladder. Bladder 402 may be enclosed in a casing that is not water-tight in order to protect bladder 402 from damage by external objects.

Persons skilled in the art will appreciate that the principles of the present invention can be practiced by other than the described embodiments, which are presented for purposes of illustration and not of limitation, and the present invention is limited only by the claims which follow.

What is claimed is:

1. A submersible device, comprising:
a casing;
circuitry;
a power source; and
fluid that fills a cavity formed by at least one of the circuitry and the power source.

2. The submersible device of claim 1, further comprising a bladder attached to the casing that allows flow of the fluid from and to the casing.

3. The submersible device of claim 2, wherein the casing and the enclosure are waterproof.

4. The submersible device of claim 3, wherein the circuitry comprises an emitter.

5. The submersible device of claim 4, wherein the emitter is a radio emitter and a portion of an antenna of the radio emitter is contained within the bladder.

6. The submersible device of claim 5, wherein the fluid does not affect performance of the antenna.

7. The submersible device of claim 4, wherein the emitter is a light emitter and the fluid is transparent.

8. The submersible device of claim 7, wherein the fluid does not affect performance of the light emitter.

9. The submersible device of claim 4, wherein the emitter is a position indicating emitter.

10. The submersible device of claim 1 further comprising an aperture in the casing that provides the fluid an access into and out of the casing, and that may be sealed.

11. The submersible device of claim 10, wherein the aperture may be sealed using a sealing screw and an “O” ring.

12. The submersible device of claim 2, further comprising:
a pressure gauge; and
a valve-like device in the structure that allows the pressure gauge to control flow of the fluid between the casing and the bladder.

13. A method for alleviating impact of pressure on a submersible device, comprising:
providing a casing as part of the submersible device;
filling an interior space of the casing with fluid; and
sealing the casing so that water cannot get into the casing and so that the fluid cannot get out of the casing.

14. A method for alleviating impact of pressure on a submersible device, comprising:
providing a casing as part of the submersible device;
filling an interior space of the casing with fluid;
providing a bladder that is coupled to the casing to permit a flow of the fluid from and to the interior space of the casing; and
sealing the casing so that water cannot get into the casing and so that the fluid cannot get out of the casing except into the bladder.

15. A method for alleviating impact of underwater pressure on an emitter device, comprising:
providing a casing of the emitter device;
providing a power source;
providing an emitter that is coupled to the power source;
filling an interior space of the casing with fluid;
providing an antenna that is coupled to the emitter;
providing a bladder;
positioning the antenna so that the antenna is positioned within the bladder so that the fluid can flow from and to the interior space of the casing; and
sealing the casing so that water cannot get into the casing and so that the fluid cannot get out of the casing except into the bladder.
